(19) United States
(12) Patent Application Publication
(10) Pub. No.: US 2024/0332048 A1
(43) Pub. Date: Oct. 3, 2024

(54) Component Carrier With Solder Mask Having Curved Sidewalls Interacting With Legend Marking

(71) Applicant: AT&S Austria Technologie & Systemtechnik AG, Leoben (AT)

(72) Inventors: Thomas Kristl, Trofaiach (AT); Gerhard Schmid, Trofaiach (AT)

(21) Appl. No.: 18/193,461

(22) Filed: Mar. 30, 2023

(51) Int. Cl. H01L 21/67; H01L 23/544

(52) U.S. Cl. CPC H01L 21/67282; H01L 23/544; H01L 21/68

(57) ABSTRACT

A component carrier includes a stack having at least one electrically conductive layer structure and at least one electrically insulating layer structure, a solder mask arranged at least on part of an exterior surface of the stack, said solder mask being patterned for defining curved sidewalls, and a legend marking on and/or above the stack, in direct physical contact with the solder mask and at least partially interacting with the curved sidewalls. A method for manufacturing the component carrier is also disclosed.

### TECHNICAL FIELD

Embodiments disclosed herein relate to a component carrier and a method for manufacturing a component carrier, respectively.

### BACKGROUND ART

In the context of growing product functionalities of component carriers equipped with one or more components and increasing miniaturization of such components as well as a rising number of components to be connected to the component carriers such as printed circuit boards or component carriers, increasingly more powerful array-like components or packages having several components are being employed, which have a plurality of contacts or connections, with smaller and smaller spacing between these contacts. In particular, component carriers shall be mechanically robust and electrically reliable so as to be operable even under harsh conditions.

With a legend marking, an exterior surface of a component carrier can be provided with useful readable information. Such information may comprise an indication of an identity and/or an intended position of a component of the component carrier or a link to an information source (for instance by a QR code). However, a legend marking may be damaged when a component carrier is used under harsh conditions.

### SUMMARY

There may be a need to form a component carrier having a legend marking being robust against damage.

According to an exemplary embodiment of the disclosure, a component carrier is provided which comprises a stack including at least one electrically conductive layer structure and at least one electrically insulating layer structure, a solder mask arranged at least on part of an exterior surface of the stack, said solder mask being patterned for defining curved sidewalls, and a legend marking on and/or above the stack, in direct physical contact with the solder mask and at least partially interacting with the curved sidewalls.

According to another exemplary embodiment of the disclosure, a method of manufacturing a component carrier is provided, wherein the method comprises providing a stack comprising at least one electrically conductive layer structure and at least one electrically insulating layer structure, forming a solder mask at least on part of an exterior surface of the stack, said solder mask being patterned for defining curved sidewalls, and forming a legend marking on and/or above the stack, in direct physical contact with the solder mask and at least partially interacting with the curved sidewalls.

### Overview of Embodiments

In the context of the present application, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board (PCB), an organic interposer, and an IC (integrated circuit) substrate. A component carrier may also be a hybrid board combining different ones of the above-mentioned types of component carriers.

In the context of the present application, the term “stack” may particularly denote a flat or planar sheet-like body. For instance, the stack may be a layer stack, in particular a laminated layer stack or a laminate. Such a laminate may be formed by connecting a plurality of layer structures by the application of mechanical pressure and/or heat. Preferably, the stacked layer structures may be arranged parallel to each other.

In the context of the present application, the term “layer structure” may particularly denote a continuous layer, a patterned layer or a plurality of non-consecutive islands within a common plane.

In the context of the present application, the term “patterned solder mask” or solder resist may particularly denote an electrically insulating material applied to at least part of one or both opposing main surfaces of a component carrier in order to protect surface portions of the component carrier covered with solder mask from solder which shall be applied to exposed electrically conductive pads and/or electrically conductive traces of the component carrier only. The material of the solder mask may be capable of repelling solder or for preventing solder to remain attached to the solder mask. The term “solder” may denote a low-melting alloy (for example based on lead, tin and/or silver) which may be used for joining metals. The solder mask may be patterned or structured so that portions of the component carrier surface are defined where solder may adhere since solder mask material is absent, and portions may be defined where solder is absent since solder mask material is present. For instance, it is possible to form such a solder resist on an entire main surface of a stack and to subsequently pattern the layer of solder resist, for example by a lithography and a wet chemical process (for example a solder resist stripping) or by laser processing. As a result, it may be possible to expose with respect to the solder mask one or more electrically conductive surface portions, which shall be used for electrically coupling the component carrier to an electronic periphery or a component mounted thereon. Additionally and/or alternatively, it may be possible to expose with respect to the solder mask one or more electrically insulating surface portions, required for applications, for example high frequency applications. A solder mask or resist may protect covered electrically conductive structures (for instance copper surfaces) against oxidation or corrosion, in particular surface portions containing copper. Additionally and/or alternatively, a solder mask or resist may protect covered electrically insulating structures from degradation, for example by oxygen and/or water (for instance in the form of steam).

In the context of the present application, the term “curved sidewalls” may particularly denote sidewalls of the patterned solder mask which deviate from a straight (in particular vertical) shape. In particular, the curved sidewalls may be at least partially inclined with respect to a vertical direction and may comprise at least one rounded portion. In particular, the sidewalls may be partially or completely curved. For instance, only an external portion of the sidewall may be curved. Along the thickness direction of the component carrier, the sidewalls defining the pattern of the solder mask may be not linear straight. For example, the curved sidewalls may comprise at least one convex portion, at least one concave portion, at least one straight portion and/or at least one inclined portion. Preferably, the curved sidewalls may extend from a base structure under the patterned solder mask with a convex shape until they reach a maximum and/or a plateau. Such a curved solder mask may be manufactured by applying a preform of the solder mask with appropriate properties (for instance in terms of viscosity, curing behavior, etc.) that a patterning and/or curing process leads to curved rather than vertical sidewalls. Forming a solder mask may be formed for instance in the following ways: In one embodiment, the solder mask may be supplied as a liquid precursor (for example liquid epoxy) which may be applied (for example by screen printing) on the stack of the component carrier (for example through a stencil). In another embodiment, the preform of the solder mask may be a photoimageable liquid ink which may be applied (for instance by screen printing or spraying) onto the stack of the component carrier. Thereafter, the preform of the solder mask may be exposed to electromagnetic radiation, in particular ultraviolet light, through a negative image of the solder mask so that selectively those areas exposed to the ultraviolet light may be cured and thereby hardened, whereas the remaining portions may be removed leaving one or more electrically conductive pads to be exposed for a surface finish, in particular soldering. In yet another embodiment, a dry film photoimageable material may be used as a precursor for forming the solder mask: The dry film solder mask precursor may be exposed to electromagnetic radiation, in particular ultraviolet light, followed by removing selectively the non-cured and thus non-hardened areas of the solder mask precursor. Hence, instead of a liquid, a dry film may be applied as a sheet of solder mask precursor film over the component carrier stack, for example by lamination. A skilled person will understand that properly adjusting the process parameters of any of the mentioned embodiments of solder mask application may lead to curved sidewalls with adjustable properties.

In the context of the present application, the term “legend marking” may particularly denote any information carrying indicator, sign, symbol or identifier applied (for example printed) at least partially on a solder mask of a component carrier. For example, such a legend marking may comprise text. A legend marking may comprise one or more legend layers, which may be in particular be patterned. Elements of information provided by a legend marking on a component carrier may be for example reference indicators labeling component types, polarity indicators labeling the polarity of certain components, component outlines indicating where components should be assembled, test points to assist with testing and troubleshooting, manufacturer information, serial numbers and/or other labeling. For example, a legend marking may be made of a colored ink, which may be for example black or white. In particular, a legend marking may be formed by applying epoxy ink using an ink stamp to place the legend marking on the component carrier (for example printed circuit board) surface.

In the context of the present application, the term “in direct physical contact” may particularly denote that at least a portion of the legend marking and at least a portion of the solder mask are directly connected with each other to form a mutual contact area and without an intermediate structure in between. The direct physical contact may be established in a straight orientation, for example in a main extension direction of the component carrier and/or in a stack thickness direction of the component carrier. In another example, the direct physical contact may be established in a curved manner. Preferably, the at least a portion of the legend marking and the at least a portion of the solder mask may have a key-lock or form closure assembly, in which the at least a portion of the legend marking is a negative-imaged body of the at least a portion of the solder mask.

In the context of the present application, the term “interacting with the curved sidewalls” may particularly denote that properties (in particular adhesion properties) of the legend marking are directly influenced by the curved sidewalls of the solder mask. In particular, the interaction between the legend marking and the curved sidewalls of the solder mask may be of such kind that the adhesion of the legend marking to the solder mask is promoted. For example, the enlarged sidewall area of the curved sidewalls of the solder mask (in particular in comparison with straight vertical sidewalls of the solder mask, which are intended in conventional approaches) may be in direct physical contact with part of the legend marking so that the adhesion of the legend marking to the component carrier stack as a whole may be enhanced. It is also possible that a direct physical connection between curved sidewalls of the solder mask and the legend marking may shield the legend marking with regard to an exterior main surface of the component carrier. Such an approach may lead to a spatial retraction of the legend marking with regard to the exterior surface, so that the latter may be exposed to harsh conditions during manufacturing and/or use of the component carrier without harming the legend marking.

In the context of the present application, the term “main surface” of a body may particularly denote one of two largest opposing surfaces of the body. The main surfaces may be connected by circumferential sidewalls. The thickness of a body, such as a stack, may be defined by the distance between the two opposing main surfaces.

According to an embodiment of the disclosure, a layer stack-type component carrier (such as a printed circuit board (PCB) or an integrated circuit (IC) substrate) is provided which comprises at an exterior surface a patterned solder mask with at least partially curved and thus slanted sidewalls. Advantageously, a legend marking on and/or above the stack may be directly contacted with the solder mask so as to interact with the curved sidewalls. This may lead to a better protection of the legend marking against mechanical impact which may be exerted to an exterior main surface of the component carrier during manufacture and/or use. Descriptively speaking, curved sidewalls of the solder mask may increase the connection surface area between the patterned solder mask and the legend marking in comparison with straight vertical sidewalls, so that the adhesion of the legend marking interacting with direct physical contact with the enlarged area of the curved sidewalls of the solder mask may be enhanced. Undesired removal of legend marking material when exposed to harsh conditions at an exterior main surface of the component carrier may therefore be efficiently suppressed or even eliminated. This may allow to reliably maintain important information provided by the legend marking (for example identification information used for traceability, and/or information concerning a component to be surface mounted on the component carrier).

In the following, further exemplary embodiments of the component carrier and the method will be explained.

In an embodiment, the legend marking is arranged at a position of the component carrier to be visible from a top side of the component carrier. In particular, the legend marking may be optically visible, for instance for a human operator, at at least one wavelength in the wavelength range from 400 nm to 800 nm. For example, the legend marking may be black, white, grey, or brown. Additionally or alternatively, the legend marking may be optically detectable, for instance by a machine or detector, at at least one wavelength of ultraviolet light, in particular at at least one wavelength in a range from 10 nm to 400 nm. This may bring the advantage of having legend ink detectable for machines for different applications and/or processes however not interfering with the human vision range.

In an embodiment, the legend marking comprises an alphanumerical code, a location indicator, a QR code, a barcode, a logo and/or an icon. For example, a legend marking comprising alphanumerical code may comprise or consist of human readable text including letters and/or figures. Additionally or alternatively, a legend marking may comprise a location indicator indicating a location, position or area of a constituent of the component carrier, such as a location, position or area at which a surface mounted component is assembled or is to be assembled. Information included in or accessible by the legend marking may be encoded by a code, for instance in form of a QR code or a barcode. The legend marking may also be a symbol, logo and/or icon which may for example indicate the origin of the component carrier or part thereof. It is possible that the legend marking provides information as to how to use the component carrier, for example may indicate an assembling position of a component and/or may indicate a type of component to be assembled on the stack. For example, the legend marking may provide a unique identifier for the component carrier.

In an embodiment, the legend marking comprises or consists of a dielectric ink or a dielectric film. Thus, the legend marking may be electrically insulating and may not interfere with the electric functionality of the component carrier.

In an embodiment, the legend marking comprises or consists of an electrically conductive material. Thus, the legend marking may contribute to the electrical properties or the electronic functionality of the component carrier. For example, the legend marking may comprise electrically conductive particles inside a dielectric matrix. It is also possible that the legend marking comprises a magnetic material, for instance ferrite beads. For example, the legend marking may be formed using an electrically conductive coating material on electrically insulating particles. It is also possible that the legend marking is made entirely of electrically conductive material (for example pure copper). This may bring the advantage of selective and easier recognition of the legend marking, since this may have a typical appearance, for example color and/or luster.

In an embodiment, the electrically conductive material of the legend marking provides an electrically conductive connection trace being electrically connected to the stack. In such an embodiment, the legend marking may fulfill a double function, i.e., providing information in visible form and forming part of the wiring structure of the component carrier stack.

In an embodiment, at least part of the legend marking is embedded in the solder mask. Advantageously, the legend marking may be partially or entirely formed inside of the solder mask so as to be separated and thereby protected from an exterior main surface of the component carrier. For instance, legend marking material may be fully circumferentially surrounded by material of the solder mask and/or of the stack. Consequently, the embedded at least part of the legend marking may be arranged below an exterior surface of the component carrier. Thus, the legend marking may be sufficiently protected while still fulfilling the required purpose of for example acting as a visual mark.

In an embodiment, the at least part of the legend marking is embedded in an interior of the solder mask so that the legend marking remains visible from an exterior of the component carrier. For example, this may be accomplished by locating the legend marking below a thin film of solder mask which is sufficiently thin so that it is still optically transparent. By taking this measure, the marking function of the legend marking may be guaranteed while simultaneously reliably protecting the legend marking against mechanical and chemical impact exerted to a main surface of the component carrier. For example, the total thickness of solder mask and/or legend marker material in stack thickness direction may be less than 100 μm. If the entire legend marking is embedded in the solder mask, the distance between the exposed surface of the solder mask to the nearest surface of the legend marker may be less than 10% of the entire solder mask thickness or may be less than 10 μm.

In an embodiment, an outermost exterior surface of the legend marking is retracted with respect to an outermost exterior surface of the solder mask. In other words, the solder mask may vertically protrude beyond the legend marking and may thereby protect the legend marking from mechanical impact. In case of a mechanical impact by an exterior body, said body may hit the protruding portion of the solder mask while the spatially retracted legend marking may remain intact.

In an embodiment, an outermost exterior surface of the legend marking is in flush with an outermost exterior surface of the solder mask. Also in such an embodiment, a legend marking protruding vertically beyond the exterior surface of the solder mask may be prevented, which may also provide protection of the legend marking against damage. By vertically aligning exterior surfaces of legend marking and solder mask, an excessive exterior surface profile is prevented. This may improve the overall mechanical integrity of the component carrier.

In an embodiment, at least part of the solder mask is formed on the legend marking. Hence, at least part of the legend marking material may be covered by solder mask material in a protective way.

In an embodiment, at least part of the legend marking is formed directly on at least part of the at least one electrically conductive layer structure. Advantageously, at least part of the legend marking may then be protected against an exterior exposure by being arranged directly on the stack. This may reduce the risk of damage by mechanical impact from an exterior side of the component carrier. Furthermore, the legend marking may cover the at least one electrically conductive layer structure and may therefore protect the latter, for instance against mechanical load and chemical impact (for example corrosion or oxidation).

In an embodiment, the patterned solder mask has convex sidewalls. The convex sidewalls may be entirely convex, or partially convex and partially concave and/or straight. For example, an angle between the stack surface and a line tangent to the curved sidewall of the solder mask intersecting a contact point between the solder mask sidewall and the stack surface may be at least 50°, in particular at least 60°, preferably at least 70°, for instance in a range from 20° to 80°.

In another embodiment, the patterned solder mask has concave sidewalls. The concave sidewalls may be entirely concave, or partially concave and partially convex and/or straight.

In an embodiment, the legend marking has curved sidewalls. Such sidewalls may be formed when forming the legend marking patterned or structured. “Curved sidewalls of the legend marking” may particularly denote sidewalls of the legend marking which deviate from a straight (in particular vertical) shape. In particular, the curved sidewalls may be at least partially inclined with respect to a vertical direction and may comprise at least one rounded portion. In particular, the sidewalls may be partially or completely curved. For instance, only an external portion of the sidewall may be curved. Along the thickness direction of the component carrier, the sidewalls defining the legend marking may be not linear straight. For example, the curved sidewalls of the legend marking may comprise at least one convex portion, at least one concave portion, at least one straight portion and/or at least one inclined portion. For example, the curved sidewalls may extend from a base structure under the legend marking with a convex shape until they reach a maximum or plateau. Such a curved legend marking may be manufactured by applying material of the legend marking with such properties (for instance in terms of viscosity, curing behavior, etc.) that the manufacturing process leads to curved rather than vertical sidewalls. A skilled person will understand that properly adjusting the process parameters of legend marking application, for instance by printing, may lead to curved sidewalls with adjustable properties. For example, an angle between the stack surface and a line tangent to the curved sidewall of the legend marking may be in a range from 20° to 70°.

In an embodiment, the curved sidewalls of the legend marking are in direct physical contact with the curved sidewalls of the solder mask. By directly contacting curved sidewalls of legend marking and solder mask their mutual adhesion may be strongly improved by an increase of the mutual contact area as compared to completely straight sidewalls of legend marking and solder mask. For example, a merging or intersection region between a curved sidewall of the solder mask and curved sidewalls of the legend marking may be beak-shaped (see for instance FIG. 4).

In an embodiment, an exterior surface of a section of the patterned solder mask between curved sidewalls has a profile comprising at least one local protrusion. Descriptively speaking, such a local protrusion may function as an exterior bumper for buffering mechanical stress and preventing the mechanical stress from being exerted directly to the legend marking.

In an embodiment, the solder mask and the legend marking comprise materials having different color and/or different light refraction index. This may allow a user or a machine to optically distinguish solder mask and legend marking. However, the solder mask material and the legend marker may have similar surface properties.

In an embodiment, a part of the solder mask is exposed beyond the legend marking and another part of the solder mask is covered by the legend marking. This may form an anchor structure (see FIGS. 8, 9) in which parts of the legend marking is covered by the solder mask material. This ensures that the legend ink is more difficult to remove by a mechanical force since a part of the material is hidden below the exposed surface.

In an embodiment, a part of the legend marking arranged between said part and said other part of the solder mask is formed with an undercut. The other part of the solder mask being covered by the legend marking may be formed as an undercut. Preferably, an anchor structure is provided in an undercut (with respect to stack thickness direction). Such an undercut may be delimited by solder mask material and filled with legend marking material. This provides an excellent protection of the legend marking against removal from the stack surface.

In an embodiment, the at least one electrically conductive layer structure is in direct physical contact with the solder mask and the legend marking. Hence, the solder mask and the legend marking may collaborate for protecting metallic pads against soldering, corrosion, oxidation, etc.

In an embodiment, at least one component, which may be surface mounted above the stack or embedded in the stack, is in direct physical contact with the solder mask and/or the legend marking. Thus, portions of the component which are not to be electrically connected (i.e., component portions apart from pads) may connect directly to solder mask and/or legend marking. This may increase the integrity of the component and ensures reliable function of the at least on component.

In an embodiment, the solder mask and/or the legend marking comprises a plurality of filler particles. The plurality of filler particles may have different sizes, for example in the nanometer range (1-1000 nm) and/or in the micrometer range (1-1000 μm) and/or different shapes, for example round shapes (e.g., spheres) and/or edged shapes (e.g., cubes). The plurality of filler particles may comprise or consist of inorganic material, for example glass and/or metal and/or ceramic. The plurality of filler particles may impart higher roughness to the surfaces of the solder mask and/or the legend marking, in particular to the respective curved sidewalls. This may bring the advantage of better adhesion between the solder mask and the legend marking, since the surface area is enlarged.

In an embodiment, the patterned solder mask has a maximum in vertical direction between a respective one of the curved sidewalls and a plateau region. Descriptively speaking, such a local maximum may function as an exterior bumper for buffering mechanical stress. Referring to FIG. 7, a corner region (for example a region next to a cavity) of the solder mask may have a higher total value in stack thickness direction. After ink jetting, there may be no further polishing process. Thus, it may be possible that a layer forming the solder mask and/or a layer forming the legend marking is/are not totally flat.

In an embodiment, the method comprises forming the legend marking after forming the solder mask. This may be advantageous, because it may lead to very low contamination.

Alternatively, the method comprises forming the solder mask after forming the legend marking. This may result in a proper anchoring of the legend marking by overlapping portions of the solder mask.

Hence, depending on the legend marking characteristics, it may be flexibly selected whether first the legend marking or first the solder mask is formed.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact.

In an embodiment, the component carrier is shaped as a plate. This contributes to the compact design, wherein the component carrier nevertheless provides a large basis for mounting components thereon. In particular a naked die as example for an electronic component can be surface mounted on a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). A printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo- and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, Melamine derivates, Polybenzoxabenzole (PBO), bismaleimide-triazine resin, polyphenylene derivate (e.g. based on polyphenylenether, PPE), polyimide (PI), polyamide (PA), liquid crystal polymer (LCP), polytetrafluoroethylene (PTFE), Bisbenzocyclobutene (BCB) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g., fibers impregnated with the above-mentioned resins is called prepreg. These prepregs are often named after their properties e.g., FR4 or FR5, which describe their flame retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten and magnesium. Although copper is usually preferred, other materials or coated versions thereof are possible as well, in particular materials coated with supra-conductive material or conductive polymers, such as graphene or poly(3,4-ethylenedioxythiophene) (PEDOT), respectively.

The at least one component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be surface mounted on the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded therein. Moreover, also other components, in particular those which generate and emit electromagnetic radiation and/or are sensitive with regard to electromagnetic radiation propagating from an environment, may be used as component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable. A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

The aspects defined above and further aspects of the disclosure are apparent from the examples of embodiment to be described hereinafter and are explained with reference to these examples of embodiment.

### BRIEF DESCRIPTION OF THE DRAWINGS

FIG. 1 illustrates a cross-sectional view of a component carrier according to an exemplary embodiment of the disclosure.

FIG. 2 illustrates a cross-sectional view of a component carrier according to another exemplary embodiment of the disclosure.

FIG. 3 illustrates a cross-sectional view of a component carrier according to another exemplary embodiment of the disclosure.

FIG. 4 illustrates a cross-sectional view of a component carrier according to another exemplary embodiment of the disclosure.

FIG. 5 illustrates a cross-sectional view of a component carrier according to another exemplary embodiment of the disclosure.

FIG. 6 illustrates a cross-sectional view of a component carrier according to another exemplary embodiment of the disclosure.

FIG. 7 illustrates an image of a component carrier according to another exemplary embodiment of the disclosure.

FIG. 8 illustrates a cross-sectional view of a component carrier according to another exemplary embodiment of the disclosure.

FIG. 9 illustrates a cross-sectional view of a component carrier according to another exemplary embodiment of the disclosure.

FIG. 10 illustrates an image of a component carrier according to another exemplary embodiment of the disclosure.

FIG. 11 illustrates an image of a component carrier according to another exemplary embodiment of the disclosure.

FIG. 12 illustrates an image of a portion of a component carrier according to another exemplary embodiment of the disclosure.

FIG. 13 illustrates an image of another portion of the component carrier according to FIG. 12.

FIG. 14 illustrates an image of still another portion of the component carrier according to FIG. 12.

### DETAILED DESCRIPTION OF ILLUSTRATED EMBODIMENTS

The illustrations in the drawings are schematically presented. In different drawings, similar or identical elements are provided with the same reference signs.

Before, referring to the drawings, exemplary embodiments will be described in further detail, some basic considerations will be summarized based on which exemplary embodiments of the disclosure have been developed.

In conventional component carrier manufacture, a legend marking (for instance providing identification information) may be printed on the component carrier after a solder mask process. Applied legend marking ink may form a protrusion being exposed at an exterior main surface of the component carrier. Thus, a legend marking of a conventional component carrier may be prone to damage when exposed to harsh conditions during manufacture and/or use of the component carrier. Important information provided by the legend marking may therefore be lost.

According to an embodiment of the disclosure, a (preferably laminated) layer stack of a component carrier (for example a PCB or an IC substrate) may be equipped with a solder mask formed with curved (rather than vertical straight) sidewalls. A legend marking, which may for example comprise identification information concerning component carrier and/or one or more components to be surface mounted thereon, may be formed with direct physical contacted with the curved sidewalls of the solder mask for ensuring a pronounced interaction and adhesion in between. As a result, the legend marking may properly adhere to the large area curved sidewalls of the solder mask. Consequently, the legend marking may be reliably safe guarded against damage due to mechanical load which may be exerted to an exposed surface of the component carrier. To put it shortly, connection area enlarging curved sidewalls may promote adhesion of the legend marking due to its direct physical contact with the sidewalls of the solder mask. It may thus be ensured that the legend marking remains intact. Advantageously, information provided by the legend marking (for example identification information concerning component carrier and/or component thereof) may remain at the component carrier even under harsh conditions.

According to an exemplary embodiment of the disclosure, a component carrier with a legend marking directly contacting a curved sidewall of a patterned solder mask is provided. To put it shortly, an exemplary embodiment provides a PCB with three-dimensionally combined solder mask and legend print features. Such an embodiment provides advantages: In particular, a legend marking directly contacting curved sidewall of a patterned solder mask offers protection against abrasion and can be manufactured in one process stage. Moreover, this may allow to flexibly adjust the properties of a legend marking on a solder mask to specific requirements of a certain application. Further advantageously, a legend marking directly contacting a curved sidewall of a patterned solder mask may be manufactured in a simple way, for example by three-dimensionally printing. An interaction between a legend marking and a physically connected curved sidewall of a patterned solder mask may provide a reliable abrasion protection. A legend marking according to an exemplary embodiment may be manufactured in a time-saving way.

In one preferred embodiment, it may be possible to stay with the legend marking (which may be embodied as identification paint) under the solder mask so that it may be possible to achieve a mechanical protection against abrasion. Furthermore, the manufacturing effort for a legend marking in combination with a solder mask may be significantly reduced, because critical process stages may be bypassed or combined (for instance inkjet printing and legend printing).

According to an exemplary embodiment, a component carrier (for example, a PCB) with a three-dimensionally combined solder mask and legend marking is provided. By a multi-layer structure, thus three-dimensionally, it may be possible according to an exemplary embodiment of the disclosure to realize solder mask and legend marking (also called component printing) by increasing the mechanical integrity of the component carrier.

For this purpose, for example, the solder mask can be applied in different layers. In one of the layers, channels can be created with a legend marking (for example formed by another varnish or filler). This may create an optically distinguishable structure with the function of a solder mask and a protected legend marking. For example, the channel can be filled to approximately or exactly the same level as the solder stopper. It is also possible to realize the optically visible legend marking with an additional layer of solder mask by adding an additional web or rib. It may also be possible to create channels by a solder mask, which may emanate from a laminate stack. The channels can then be completely filled by a component printing varnish or a legend marking or with other varnishes, fillers or the like. As a result, an optical distinguishable line can be achieved. In particular, the legend marking can be realized without the risk of abrasion.

In an embodiment, solder mask and legend marker can be formed on one vertical level. It is also possible to integrate a legend marking in a solder mask. By an appropriate machine or process, the two coatings can, for example, be brought to the same vertical level.

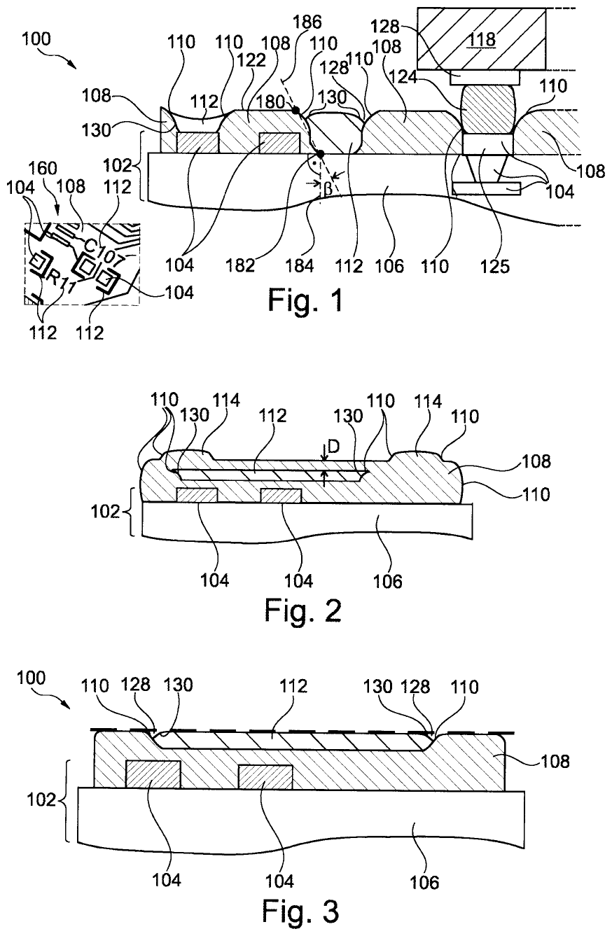

FIG. 1 illustrates a cross-sectional view of a component carrier 100 according to an exemplary embodiment of the disclosure.

For example, the component carrier 100 may comprise a laminated layer stack 102 comprising a plurality of electrically conductive layer structures 104 and of electrically insulating layer structures 106. The electrically conductive layer structures 104 may comprise patterned copper layers which may form horizontal pads and/or a horizontal wiring structure. Additionally or alternatively, the electrically conductive layer structures 104 may comprise vertical through connections such as copper pillars and/or copper filled laser vias. Moreover, the stack 102 of the component carrier 100 may comprise one or more electrically insulating layer structures 106 (such as prepreg or resin sheets). Also surface finish (like ENIG or ENEPIG, etc.) may be applied on the top side and/or on the bottom side of the stack 102. The uppermost electrically insulating layer structure in FIG. 1 is solder mask 108 or solder resist. Solder mask 108 may support correct intermetallic connection, for example soldering, of a surface mounted component 118 and of component carrier 100 on a mounting base below (not shown, for example a further printed circuit board).

As shown, the illustrated component carrier 100 comprises the electronic component 118 mounted by a solder structure 124 on the component carrier 100. More specifically, a pad 125 of an electrically conductive layer structure 104 at an upper main surface of the stack 102 is solder-connected by the solder structure 124 with an electrically conductive pad 125 at a bottom main surface of the component 118. Alternatively, a number of electronic components 118 being surface mounted on the component carrier 100 may be at least two. Additionally or alternatively to the surface mounted component 118, it is also possible to embed one or more electronic components 118 in the component carrier 100.

The electronic component 118 is here configured as bare die (i.e., non-encapsulated semiconductor chip) and is surface mounted on a top main surface of the component carrier 100. The electronic component 118 may be configured as semiconductor chip, for instance active semiconductor chip. Examples of the IC-type electronic component 118 are processors, memories, sensors, logic chips, microelectromechanical systems (MEMS), etc. The electronic component 118 may comprise an integrated circuit with at least one monolithically integrated circuit element, such as a transistor or a diode, in an active region. The electronic component 118 can also be a stacked IC, a module, a chiplet or a system-on-chip (SoC).

As already mentioned, the component carrier 100 comprises a structured or patterned layer of solder mask 108 arranged at an exterior surface of the stack 102. More specifically, said solder mask 108 is patterned for defining curved sidewalls 110 delimiting one or more recesses 128 of the patterned solder mask 108.

Referring to FIG. 1, the curved sidewalls 110 the solder mask 108 may be formed between an upper reference point 180 and a lower reference point 182. Upper reference point 180 corresponds to a position where the curved sidewall 110 starts by kinking or deviating from a horizontal plateau region 122 of the solder mask 108. Lower reference point 182 corresponds to a position where the curved sidewall 110 ends. An angle ß (which is not drawn true to scale in FIG. 1) between a slanted straight connection line 186 between reference points 180, 182 and a vertical line 184 is for example at least 50°, in particular at least 60°, preferably at least 70°, for instance in a range from 20° to 80°.

As shown, the curved sidewalls 110 have a convex shape. Shape, curvature, slanting angles, etc. of the curved sidewalls 110 may be adjusted by correspondingly adjusting the manufacturing properties when forming the solder mask 108, for instance in terms of selecting resin material, viscosity, patterning process, etc. The solder mask 108 may be made of a dielectric material on which solder material does not adhere. Furthermore, the solder mask 108 may cover at least one electrically conductive layer structure 104 on an exposed main surface of the stack 102 to thereby protect the metallic surface thereof against corrosion or oxidation. For example, the solder mask 108 may be a dielectric colorful material, in particular of green color.

Moreover, component carrier 100 comprises a legend marking 112 which may be an integral structure or may be composed of different separate sections. For instance, legend marking 112 may be of white color. For example, the legend marking 112 comprises a dielectric ink. However, it is also possible that the legend marking 112 comprises an electrically conductive material. For example, the legend marking 112 comprises an alphanumerical code, such as text, or a QR code or other machine-readable code. Such a code may encode information which is useful for a user or a device, for instance for identifying the component carrier 100 (for example serving as a unique identifier) or for indicating an intended use of the component carrier 100 (for instance indicating at which position which kind of component 118 to be assembled.

Just as an example and referring to a detail 160 in FIG. 1, the legend marking 112 may comprise signs such as “C107” for indicating that a capacitor component #“107” shall be mounted at an indicated position on the surface of the component carrier 100. Furthermore, the legend marking 112 may comprise signs such as “R11” for indicating that a resistor component #“11” shall be mounted at an indicated position on the surface of the component carrier 100.

In the shown embodiment, legend marking 112 is formed partially on solder mask 108, is formed partially on an electrically insulating layer structure 106 of stack 102 and partially on an electrically conductive layer structure 104 of the stack 102. As shown, said electrically conductive layer structure 104 is in direct contact with both the solder mask 108 and the legend marking 112. Said different portions of the legend marking 112 may extend from different vertical levels, as shown in FIG. 1. Each section of the legend marking 112 is formed in a respective recess 128 of the solder mask 108. Furthermore, each section of the legend marking 112 has curved sidewalls 130. The curved sidewalls 130 may have a convex and/or a concave shape. Shape, curvature, slanting angles, etc. of the curved sidewalls 130 may be adjusted by correspondingly adjusting the manufacturing properties when forming the legend marking 112, for instance in terms of selecting resin material, viscosity, patterning process, etc.

As shown in FIG. 1 as well, sections of the legend marking 112 with the curved sidewalls 130 are in direct physical contact with the curved sidewalls 110 of the solder mask 108 and therefore interact with the curved sidewalls 110. This enhances adhesion between material of the legend marking 112 and material of the solder mask 108 and therefore improves the mechanical integrity of the component carrier 100 as a whole.

According to FIG. 1, an outermost exterior surface of the legend marking 112 is retracted with respect to an outermost exterior surface of the solder mask 108. In other words, solder mask 108 vertically protrudes beyond the legend marking 112. As a result, the legend marking 112 is protected against exterior mechanical impact by the solder mask 108. This efficiently suppresses undesired abrasion of the legend marking 112 by directly exerted mechanical load. Due to the described geometry of the legend marking 112, the legend marking 112 is arranged to be visible from a top side of the component carrier 100, i.e., in a vertical viewing direction according to FIG. 1. Thus, the functionality of legend marking 112 is reliably maintained although it is mechanically protected by being retracted with respect to the solder mask 108.

Preferably, the solder mask 108 and the legend marking 112 comprise materials having different optical properties, in particular different colors and/or different light refraction index. This ensures that the legend marking 112 remains visible by a human being or an optical camera despite of it spatial vicinity to the solder mask 108.

During manufacture of component carrier 100 according to FIG. 1, the legend marking 112 may be formed after forming the solder mask 108. Advantageously, this may reliably suppress contamination.

In the shown embodiment, the component 118 is mounted above the solder mask 108 and the legend marking 112. Alternatively, it is however possible that the component 118 is in direct contact with the solder mask 108 and/or the legend marking 112 (not shown).

Still referring to FIG. 1, cavities or recesses 128 of solder mask 108 may be formed in the place of a desired or required legend image which may be filled with a different color varnish to thereby form legend marking 112. As shown, the legend ink material of legend marking 112 is located below the height of the ink forming the solder mask 108. This provides a mechanical protection of the legend ink due to recesses 128 of the solder mask 108 being only partially filled with legend ink of legend marking 112. Such a configuration may be realized in one process stage, for example by 3D printing. For example, an inkjet process may be executed for forming the solder mask 108.

FIG. 2 illustrates a cross-sectional view of a component carrier 100 according to another exemplary embodiment of the disclosure.

In the embodiment of FIG. 2, the legend marking 112 is entirely embedded in an interior of the solder mask 108. This may reliably protect the material of the legend marking 112 by the fully circumferentially surrounding material of the solder mask 108. Advantageously, the complete legend marking 112 is fully circumferentially embedded in the solder mask 108 in such a way that the legend marking 112 remains nevertheless visible from an exterior of the component carrier 100. This may be ensured by a sufficiently thin thickness, D, of the portion of the solder mask 108 above the legend marking 112. For instance, the sub-layer thickness, D, of the solder mask 108 above the legend marking 112 may be in a range from 1 μm to 30 μm, for example 10 μm. Advantageously, the functionality of the legend marking 112 of providing readable information may be maintained by the embodiment of FIG. 2 while simultaneously reliably protecting the legend marking 112 against abrasion and special chemical impact.

According to FIG. 2, a first part of the solder mask 108 is formed on the legend marking 112, a second part of the solder mask 108 is formed under the legend marking 112, and a third part of the solder mask 108 is formed laterally from the legend marking 112. This protects the legend marking 100 from all sides.

To further improve the protection function of the solder mask 108, an exterior surface of the patterned solder mask 108 between curved sidewalls 110 has a profile comprising one or more (in the shown embodiment two) local protrusions 114 forming the outermost surface area of component carrier 100. Descriptively speaking, the local protrusions 114 may function as mechanical bumpers for buffering mechanical stress exerted to the upper main surface of component carrier 100. The local protrusion 114 may be located directly vertically shifted with regard to stack thickness direction above the legend marking 112 (left local protrusion 114 in FIG. 2) and/or the local protrusion 114 may be above (in stack thickness direction) and additionally transversally shifted (in at least one main extension direction) with regard to the legend marking 112 (right local protrusion 114 in FIG. 2).

To prevent mechanical abrasion, legend marking 112 may be formed as a colored layer applied with a certain thickness which is then protected with a protection cover layer forming part of the solder mask 108. In addition, vertical bumpers may be provided in form of local protrusions 114 to achieve an even better additional mechanical protection.

FIG. 3 illustrates a cross-sectional view of a component carrier 100 according to another exemplary embodiment of the disclosure.

The embodiment of FIG. 3 differs from the embodiment of FIG. 2 in particular in that, according to FIG. 3, an outermost exterior surface the legend marking 112 can be (at least substantially) in flush with an outer-most exterior surface of the solder mask 108 (see dashed horizontal line). In other words, the exposed surface of the legend marking 112 and the exposed surface of the solder mask 108 are aligned with each other and are at the same vertical level. A recess 128 or cavity with closed bottom is formed in the solder mask 108, and the legend marking 112 is formed entirely in the recess 128. Preferably, the legend marking 112 does not protrude beyond the solder mask 108, but is in vertical alignment with the solder mask 108. As a result, the legend marking 112 being entirely arranged inside of the recess 128 of the solder mask 108 is protected against exterior mechanical impact. Hence, the embodiment of FIG. 3 has a top-sided solder mask indentation at the position of the legend marking 112 which may be provided with another kind of ink with another color than the material of the solder mask 108. The solder mask 108 and the legend marking 112 are in direct physical contact with each other at a bottom side of the legend marking 112 and at curved sidewalls 110, 130. Since not only the solder mask 108 but also the legend marking 112 forms part of the exposed surface of the component carrier 100, readability of the legend marking 112 is excellent while the non-protruding legend marking 112 is reliably protected against mechanical damage.

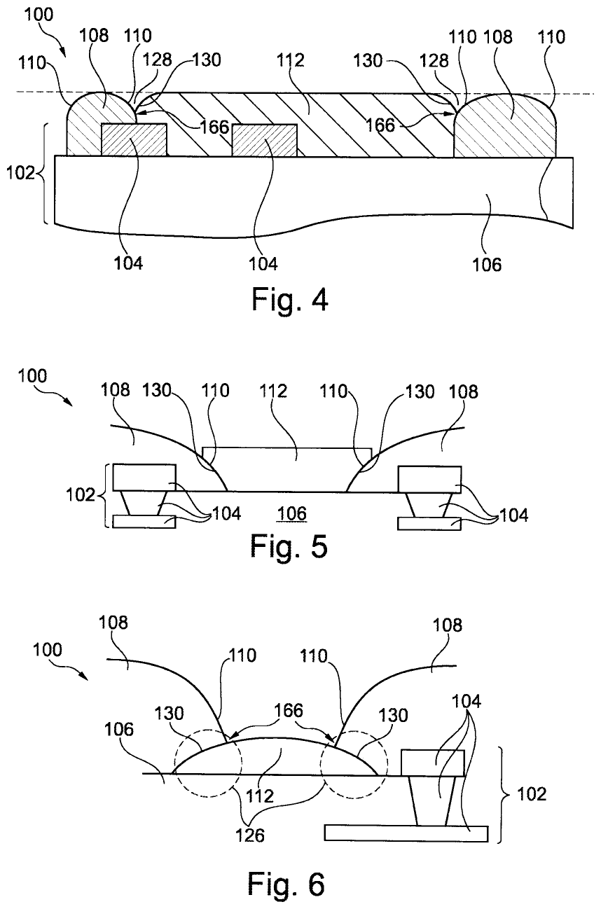

FIG. 4 illustrates a cross-sectional view of a component carrier 100 according to another exemplary embodiment of the disclosure.

The embodiment of FIG. 4 differs from the embodiment of FIG. 3 in particular in that, according to FIG. 4, the legend marking 112 is formed in a through-hole type recess 128 of the solder mask 108. Consequently, a bottom surface of the legend marking 112 is in direct physical contact with a surface of the laminated layer stack 102 of layer structures 104, 106. Also according to FIG. 4, an outermost exterior surface of the legend marking 112 may be vertically aligned with or in flush with an outermost exterior surface of the solder mask 108 (see dashed horizontal line). However, the legend marking 112 may be alternatively spatially retracted with respect to the solder mask 108 (not shown, for instance in a similar way as illustrated in FIG. 1).

According to FIG. 4, the solder mask 108 has one or more through holes at one or more positions of the legend marking 112 which may be provided with another kind of ink with another color than the material of the solder mask 108. The solder mask 108 and the legend marking 112 are in direct physical contact with each other only at curved sidewalls 110, 130. Ink material of the legend marking 112 may be filled in the through hole(s) so as to (at least partially, in particular fully) cover the exposed surface of the layer structures 104, 106.

As shown in FIG. 4 (and in FIG. 6), the curved sidewalls 130 of the legend marking 112 and the curved sidewalls 110 of the solder mask 108 may merge or intersect with a beak shape 166. Referring to FIG. 4, the curved sidewalls 130 of the legend marking 112 and the curved sidewalls 110 of the solder mask 108 approach until they meet each other in a common point or line. In this merging region between the legend marking 112 and the solder mask 108, an angle is formed between the curved sidewall 110 and the curved sidewall 130 which may have the shape of a bird beak.

FIG. 5 illustrates a cross-sectional view of a component carrier 100 according to another exemplary embodiment of the disclosure.

According to FIG. 5, concave curved sidewalls 130 of legend marking 112 are in direct physical contact with convex curved sidewalls 110 of solder mask 108. This provides a large connection surface between legend marking 112 and solder mask 108 and consequently a reliable adhesion in between. The legend marking 112 is spatially retracted in a vertical direction with respect to the solder mask 108 and is therefore reliably mechanically protected against damage.

The configuration of FIG. 5 may lead to a small exposed surface of the stack 102 being nevertheless properly covered by the legend marking 112. The small exposed PCB surface area may be promoted by the curved and slanted convex sidewalls 110 of solder mask 108. According to FIG. 5, the legend marking 112 may be formed after forming the solder mask 108. Consequently, the legend marking 112 is formed on the solder mask 108. This may reduce or even eliminate contamination issues.

FIG. 6 illustrates a cross-sectional view of a component carrier 100 according to another exemplary embodiment of the disclosure.

According to FIG. 6, portions of convex curved sidewalls 130 of legend marking 112 are in direct physical contact with concave portions of curved sidewalls 110 of solder mask 108. Also, this configuration provides a large connection surface between legend marking 112 and solder mask 108 and consequently a reliable adhesion in between. Also in FIG. 6, the legend marking 112 is exposed and is spatially retracted in a vertical direction with respect to the solder mask 108 and is therefore reliably mechanically protected against damage.

In the shown embodiment, forming the solder mask 108 may be performed after forming the legend marking 112. Consequently, the solder mask 108 is formed on the legend marking 112. Advantageously, this may lead to a proper anchoring of the legend marking 112 by overlapping portions of the solder mask 108, see reference signs 126 indicating an anchoring region. At the interface between legend marking 112 and solder mask 108, the mutual anchoring region 126 may be formed which enhances the mechanical integrity of the component carrier 100.

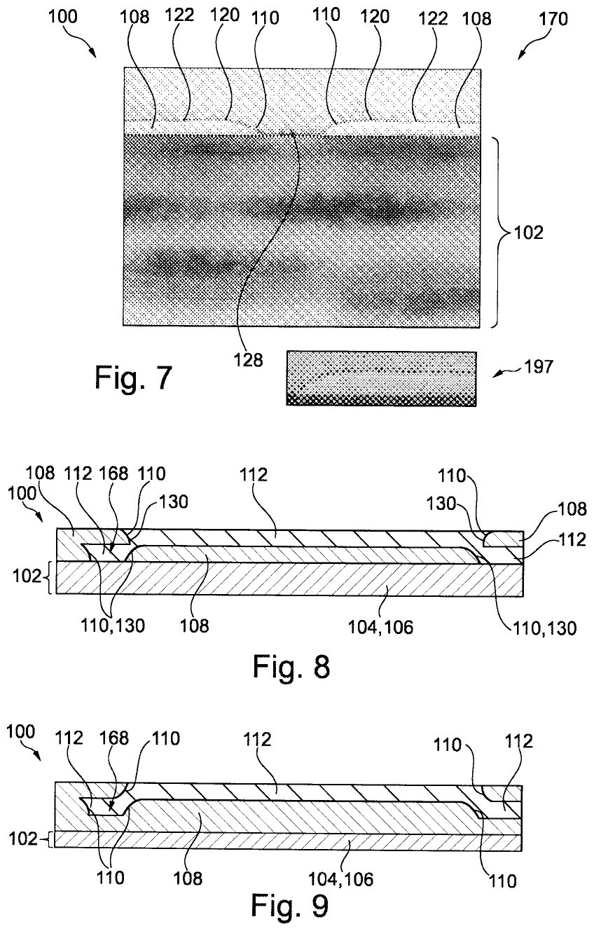

FIG. 7 illustrates an image 170 of a manufactured component carrier 100 according to another exemplary embodiment of the disclosure.

As shown in FIG. 7, the patterned solder mask 108 has a maximum 120 in vertical direction between a respective one of the convex curved sidewalls 110 and a plateau region 122, see also enlarged detail 197 of a region around the maximum 120 on the right-hand side. The legend marking 112 (not shown in FIG. 7) may be inserted in cavity 128 and may therefore be reliably protected against mechanical damage, also by the maximum 120 functioning as bumper. The illustrated configuration allows to expose only a small surface area of stack 102 and therefore provides a reliable protection against corrosion, oxidation, and other kind of exterior impact.

FIG. 8 illustrates a cross-sectional view of a component carrier 100 according to another exemplary embodiment of the disclosure.

In the embodiment of FIG. 8, an outermost exterior surface the legend marking 112 is in alignment with an outermost exterior surface of the solder mask 108. A part of the solder mask 108 is exposed beyond the legend marking 112 and another part of the solder mask 108 is covered by the legend marking 112. A part of the legend marking 112 arranged between said part and said other part of the solder mask 108 is formed with an undercut 168.

Descriptively speaking, the embodiment of FIG. 8 anchors a lower portion of the legend marking 112 between a bottom-sided portion and a top-sided portion of the solder mask 108. Furthermore, the lower and an upper portion of the legend marking 112 are arranged between lateral portions of the solder mask 108. Curved sidewalls 110 of solder mask 108 are in direct physical contact with curved sidewalls 130 of legend marking 112. Furthermore, the legend marking 112 may be exposed on the sidewall of the component carrier 100.

This configuration provides an excellent anchoring of the legend marking 112 within the solder mask 108 while preventing the legend marking 112 from protruding vertically beyond the solder mask 108. This combines a clear visibility of the legend marking 112 from an exterior side with an excellent protection of the legend marking 112 against mechanical impact from an exterior side. The bottom-sided portion of the legend marking 112 contacts at least one layer structure 104 and/or 106 of stack 102.

FIG. 9 illustrates a cross-sectional view of a component carrier 100 according to another exemplary embodiment of the disclosure.

The embodiment of FIG. 9 differs from the embodiment of FIG. 8 in that, according to FIG. 9, the bottom-sided portion of the legend marking 112 contacts the solder mask 108 (rather than at least one layer structure 104 and/or 106 of stack 102, as in FIG. 8). Furthermore, sidewalls 110, 130 have a different shape than in FIG. 8 as a result of a different order of the manufacturing process. A shape as shown in FIG. 9 may be obtained by first applying the lower portion of solder mask 108, then applying the legend marking 112, and then applying the upper portion of solder mask 108. However, many alternatives are possible. Also, with the embodiment of FIG. 9, a proper visibility of the legend marking 112 from an exterior side of component carrier 100 may be combined with an excellent protection of the legend marking 112 against mechanical impact from an exterior side.

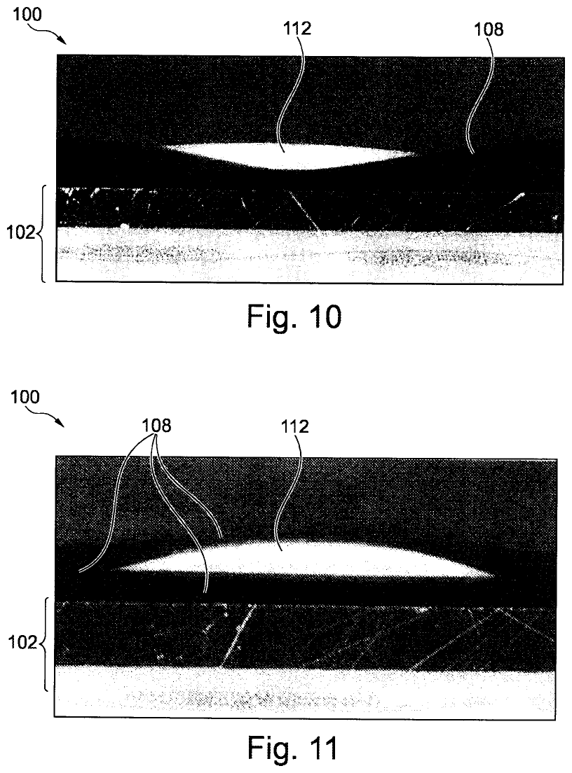

FIG. 10 illustrates an image of a component carrier 100 according to another exemplary embodiment of the disclosure. As shown, a transition region between said solder mask 108 and said legend marking 112 defines a non-planar (in the shown embodiment angled) exterior surface portion of the component carrier 100. Thus, a transition area between the legend marking 112 and the solder mask 108 may be non-planar, profiled, or structured. Recognition of the legend marking 112 of the component carrier 100 may be enhanced, since the transition region may create a more defines outline of the legend marking 108. FIG. 10 shows an image associated with the embodiment of FIG. 3. As can be seen by FIG. 10, the top of said legend marking 112 and the bottom of said legend marking 112 have convex shapes, respectively.

FIG. 11 illustrates an image of a component carrier 100 according to another exemplary embodiment of the disclosure. FIG. 11 shows an image associated with the embodiment of FIG. 2. As can be seen by FIG. 11, the bottom of said legend marking 112 is substantially flat. Compared to FIG. 2, the top of legend marking 112 has a convex shape. Furthermore, the exposed solder mask 108 vertically shifted in stack thickness direction and in direct contact with legend marking 112 also comprises a convex shape. However, the crowning of the convex shape of the legend marking 112 and the convex shape of the solder mask 108 may be different.

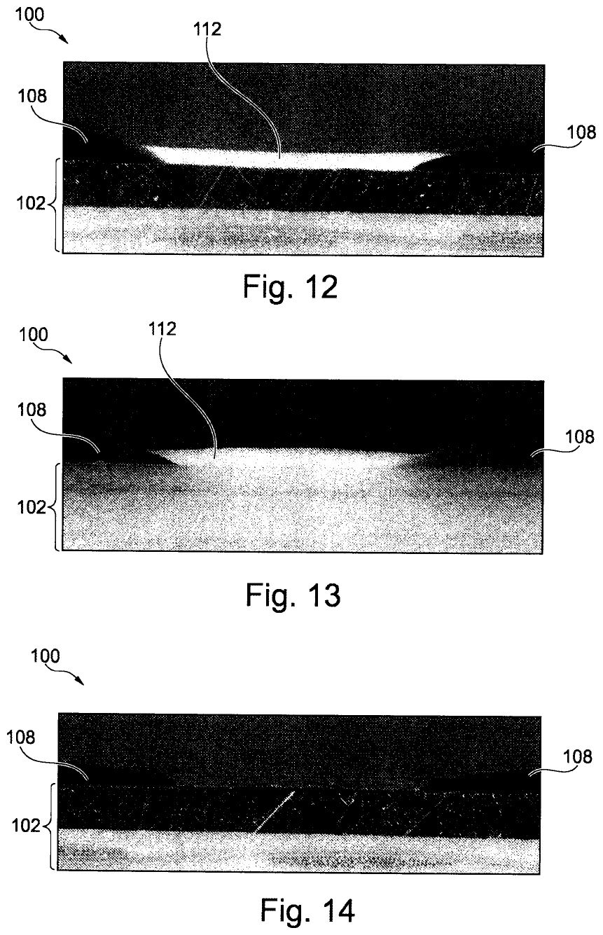

FIG. 12 illustrates an image of a portion of a component carrier 100 according to another exemplary embodiment of the disclosure. In this example, the legend marking 112 has a concave shape at its exposed portion. Furthermore, the bottom portion of the legend marking 112 and the bottom portion of the solder mask 108 are in direct contact with the stack 102, in particular the electrically conductive layer structure 104, respectively. FIG. 13 illustrates an image of another portion of the component carrier 100 according to FIG. 12. In the example, the bottom portion of the legend marking 112 and the bottom portion of the solder mask 108 are in direct contact with the stack 102, in particular the electrically insulating layer structure 106, respectively. FIG. 14 illustrates an image of still another portion of the component carrier 100 according to FIG. 12. FIG. 12 shows a structure corresponding to a portion on the left-hand side of FIG. 1, FIG. 13 shows a structure corresponding to a central portion of FIG. 1, and FIG. 14 shows a structure corresponding to a portion on the right-hand side of FIG. 1.

Additionally, as one can see from all cross sections of FIG. 10 to FIG. 14, that the exposed surface area of the legend marking 112 or the solder mask 108 covering the legend marking 112 may be non-planar.

It should be noted that the term “comprising” does not exclude other elements or steps and the article “a” or “an” does not exclude a plurality. Also, elements described in association with different embodiments may be combined.

Implementation of the disclosure is not limited to the preferred embodiments shown in the figures and described above. Instead, a multiplicity of variants is possible which variants use the solutions shown and the principle according to the disclosure even in the case of fundamentally different embodiments.

1. A component carrier, comprising:
a stack comprising at least one electrically conductive layer structure and at least one electrically insulating layer structure;
a solder mask arranged at least on part of an exterior surface of the stack, said solder mask being patterned for defining curved sidewalls; and
a legend marking on and/or above the stack, in direct physical contact with the solder mask and at least partially interacting with the curved sidewalls.

2. The component carrier according to claim 1, wherein the legend marking is arranged to be visible from a top side of the component carrier.

3. The component carrier according to claim 1, wherein the legend marking comprises an alphanumerical code, a location indicator, a QR code, a barcode, a logo and/or an icon.

4. The component carrier according to claim 1, wherein the legend marking comprises or consists of a dielectric ink or a dielectric film.

5. The component carrier according to claim 1, wherein at least part of the legend marking is embedded in the solder mask, wherein for example the at least part of the legend marking is embedded in an interior of the solder mask so that the legend marking remains visible from an exterior of the component carrier.

6. The component carrier according to claim 1, wherein an outermost exterior surface of the legend marking is retracted with respect to an outermost exterior surface of the solder mask.

7. The component carrier according to claim 1, wherein at least part of the solder mask is formed on the legend marking.

8. The component carrier according to claim 1, wherein at least part of the legend marking is formed directly on at least part of the at least one electrically conductive layer structure.

9. The component carrier according to claim 1, wherein the patterned solder mask has convex sidewalls.

10. The component carrier according to claim 1, wherein the legend marking has curved sidewalls.

11. The component carrier according to claim 10, comprising at least one of the following features:
wherein the curved sidewalls of the legend marking are in direct physical contact with the curved sidewalls of the solder mask;
wherein the curved sidewalls of the legend marking and the curved sidewalls of the solder mask merge with a beak shape.

12. The component carrier according to claim 1, wherein an exterior surface of a section of the patterned solder mask between curved sidewalls has a profile comprising at least one local protrusion.

13. The component carrier according to claim 1, wherein the solder mask and the legend marking comprise materials having different color and/or different light refraction index.

14. The component carrier according to claim 13, wherein a part of the legend marking arranged between said part and said other part of the solder mask is formed with an undercut.

15. The component carrier according to claim 1, wherein the at least one electrically conductive layer structure is in direct physical contact with the solder mask and the legend marking.

16. The component carrier according to claim 1, wherein at least one component, being surface mounted above the stack or embedded in the stack, is in direct physical contact with the solder mask and/or the legend marking.

17. The component carrier according to claim 1, wherein the patterned solder mask has a maximum in vertical direction between a respective one of the curved sidewalls and a plateau region.

18. The component carrier according to claim 1, wherein a transition region between said solder mask and said legend marking defines a non-planar, for example angled, exterior surface portion of the component carrier.

19. A method of manufacturing a component carrier, wherein the method comprises:
providing a stack comprising at least one electrically conductive layer structure and at least one electrically insulating layer structure;
forming a solder mask at least on part of an exterior surface of the stack, said solder mask being patterned for defining curved sidewalls; and
forming a legend marking on and/or above the stack, in direct physical contact with the solder mask and at least partially interacting with the curved sidewalls.

20. The method according to claim 19, wherein the method comprises forming the legend marking after forming the solder mask or forming the solder mask after forming the legend marking.
